(19) United States
(12) Patent Application Publication
(10) Pub. No.: US 2012/0280340 A1
(43) Pub. Date: Nov. 8, 2012

(54) MEMORY DEVICES AND METHODS OF MANUFACTURING THE SAME

(75) Inventors: Sun-kook Kim, Hwaseong-si (KR); Woong Choi, Seongnam-si (KR); Seung-hoon Han, Seoul (KR); Yong-wan Jin, Seoul (KR); Sang-yoon Lee, Seoul (KR)

(73) Assignee: SAMSUNG ELECTRONICS CO., LTD., Suwon-si (KR)

(21) Appl. No.: 13/462,472

(22) Filed: May 2, 2012

(30) Foreign Application Priority Data
May 3, 2011 (KR) 102011041993

(51) Int. Cl. H01L 29/82; H01L 21/8246

(52) U.S. Cl. 257/421; 438/3; 257/E29.323; 257/E21.665

(57) ABSTRACT

A memory device includes a lower electrode formed on a substrate, and an information storage unit formed on the lower electrode. The information storage unit includes a plurality of information storage layers spaced apart from one another. Each of the plurality of information storage layers is an information unit. A method of manufacturing a memory device uses a porous film to form the plurality of information storage layers.

### CROSS-REFERENCE TO RELATED APPLICATIONS

This application claims priority under 35 U.S.C. §119 to Korean Patent Application No. 10-2011-0041993, filed on May 3, 2011, in the Korean Intellectual Property Office, the disclosure of which is incorporated herein in its entirety by reference.

### BACKGROUND

1. Field

Example embodiments relate to memory devices and methods of manufacturing the same, for example, memory devices including one or more information units patterned in nanometer sizes, and methods of manufacturing the same.

2. Description of the Related Art

As increasing amounts of information need to be processed according to development of information industries, demands for data storage media to store this amount of information are continuously increasing. According to the increasing demands, studies on relatively small information storage media having quicker storage speeds are being conducted. As a result, various types of information storage apparatuses have been developed.

Conventional information storage apparatuses are largely classified as volatile information storage apparatuses and nonvolatile information storage apparatuses.

Information recorded on a volatile information storage apparatus is erased when power supplied to the volatile information storage apparatus is blocked/interrupted, but volatile information storage apparatuses have relatively quick information recording and reproducing speeds.

Information recorded on nonvolatile information storage apparatuses is not erased even when power supplied to the nonvolatile information storage apparatus is blocked/interrupted.

A representative example of a volatile information storage apparatus is a dynamic random access memory (DRAM). Examples of a nonvolatile information storage apparatus include a hard disk drive (HDD) and a nonvolatile random access memory (RAM).

A magnetic random access memory (MRAM), which is a type of a nonvolatile memory, is a memory device that uses a magnetic resistance effect based on a spin-dependent conduction phenomenon. A ferroelectric memory device uses a dipole polarized in a domain as an information unit, and reads stored information using a probe or the like. However, a size of the information unit in a ferroelectric memory device decreases as required amounts of information to be stored increase, and it may be relatively difficult to preserve data for a relatively long time because a polarization direction may not be uniformly maintained for a relatively long time due to an effect of a dipole in an adjacent domain.

### SUMMARY

At least some example embodiments provide memory device including one or more information units patterned in nanometer sizes.

At least some example embodiments also provide methods of manufacturing memory devices including one or more information units patterned in nanometer sizes.

At least one example embodiment provides a memory device including: a lower electrode formed on a substrate; and an information storage unit formed on the lower electrode. The information storage unit includes a plurality of information storage layers. Each of the plurality of information storage layers is an information unit, and the plurality of information storage layers are spaced apart from one another.

According to at least some example embodiments, the information storage unit may be formed of a ferroelectric material, a ferromagnetic material, or an antiferromagnetic material.

The memory device may further include an insulating layer formed on the lower electrode and the information storage unit.

The insulating layer may be formed of a low-k dielectric material having a dielectric constant lower than silicon oxide (SiO₂).

An interval between the plurality of information storage layers may be from several nanometers to hundreds of nanometers.

At least one other example embodiment provides a method of manufacturing a memory device. According to at least this example embodiment, the method includes: forming a lower electrode on a substrate; forming a material layer for forming an information storage unit on the lower electrode; forming a porous film for patterning the material layer on the material layer; forming a mask layer on the material layer through the porous film; and forming an information storage unit by etching the material layer using the mask layer as an etch mask.

According to at least some example embodiments, the material layer may be formed of a ferroelectric material, a ferromagnetic material, or an antiferromagneic material. The porous film may include a plurality of holes for exposing the lower electrode. The porous film may be a block copolymer or an anodized layer. The block copolymer may be poly(styrene-b-methyl methacrylate) (PS-b-PMMA), poly(styrene-block-isoprene) (PS-b-PI), poly(styrene-block-ethylene) (PS-b-PE), poly(styrene-block-ethylene propylene) (PS-b-PEP), polystyrene-block-poly(2-vinylpyridine) (PS-b-P2VP), polystyrene-block-poly(4-vinylpyridine) (PS-b-P4VP), polystyrene-block-polybutadiene (PS-b-PB), polyisoprene-block-polyferrocenylsilane (Pl-b-PFS), or polystyrene-block-poly(ethylene oxide) (PS-b-PEO).

According to at least some example embodiments, the method may further include removing the mask layer after forming the information storage unit and/or forming an insulating layer on the information storage unit.

### BRIEF DESCRIPTION OF THE DRAWINGS

Example embodiments will become apparent and more readily appreciated from the following description of the drawings in which:

FIGS. 1 and 2 are diagrams of memory devices according to example embodiments;

FIGS. 3A through 3F are diagrams for describing a method of manufacturing a memory device according to an example embodiment; and

FIG. 4 is a diagram of a memory apparatus according to an example embodiment.

### DETAILED DESCRIPTION

Example embodiments will now be described more fully with reference to the accompanying drawings, in which some example embodiments are shown. In the drawings, the thicknesses of layers and regions are exaggerated for clarity. Like reference numerals in the drawings denote like elements.

Detailed illustrative embodiments are disclosed herein. However, specific structural and functional details disclosed herein are merely representative for purposes of describing example embodiments. Example embodiments may be embodied in many alternate forms and should not be construed as limited to only those set forth herein.

It should be understood, however, that there is no intent to limit this disclosure to the particular example embodiments disclosed. On the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of this disclosure. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

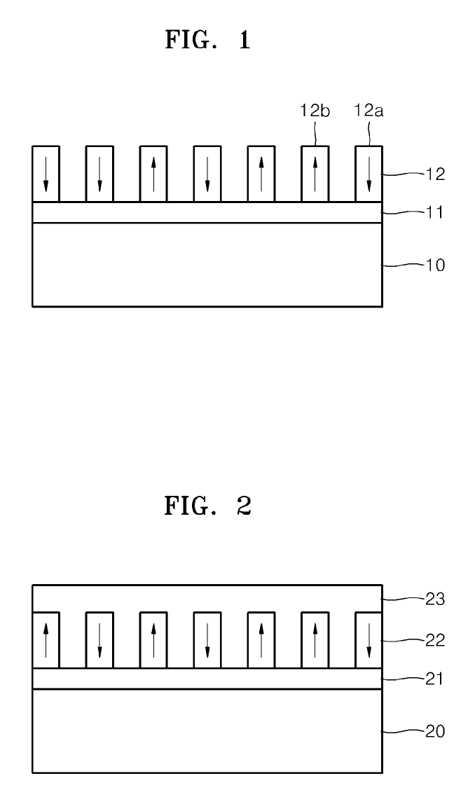

FIG. 1 is a diagram of a memory device according to an example embodiment.

Referring to FIG. 1, a lower electrode 11 is formed on a substrate 10, and an information storage unit 12 is formed on the lower electrode 11. The information storage unit 12 includes a plurality of information storage layers 12a and 12b formed on the lower electrode 11. In FIG. 1, the information storage layers 12a and 12b are spaced apart from one another. Each information storage layer 12a and 12b may constitute one information unit.

A material of the substrate 10 is not limited as long as it can be used for a general semiconductor device. For example, the substrate 10 may be formed using a semiconductor material, such as silicon (Si), silicon carbide (SiC), glass, etc. The lower electrode 11 may be formed of a conductive material used as an electrode material of a general semiconductor device. For example, the lower electrode 11 may be formed of a metal, a conductive metal oxide, etc.

The information storage unit 12 may be formed of a ferroelectric material, a ferromagnetic material, or an antiferromagnetic material. For example, the ferroelectric material may be lead zirconate titinate ((PB,Zr)TiO₃ or PZT) or bismuth ferrite (BiFeO₃ or BFO). In this example, the ferromagnetic material may be iron (Fe), cobalt (Co), nickel (Ni), manganese (Mn), gadolinium (Gd), terbium (Tb), dysprosium (Dy), holmium (Ho), an alloy thereof, or an oxide thereof, but are not limited to these examples.

In one example, the information storage unit 12 may be formed of a ferroelectric material (e.g., PZT) so that the memory device according to at least this example embodiment is a ferroelectric memory device. In this case, each of the information storage layers 12a and 12b has a spontaneous polarization characteristic, and dipoles indicating a certain polarization direction may be formed. Polarization directions of the dipoles of the information storage layers 12a and 12b may be changed by an external electric field, but the certain polarization direction is maintained when the external electric field is not applied to the information storage layers 12a and 12b.

In the example embodiment shown in FIG. 1, each of the information storage layers 12a and 12b constitutes an information unit. In one example, each information storage layer 12a and 12b may indicate “1” if the polarization directions of the dipoles are upward, but indicate “0” if the polarization directions of the dipoles are downward.

If the dipoles of the information storage layers 12a and 12b affect each other, a retention characteristic of the memory device may deteriorate. As a result, it may be relatively difficult to store information for a relatively long period of time. Accordingly, in memory devices according to at least this example embodiment, the information storage layers 12a and 12b of the information storage unit 12 may be spaced apart from one another so as to reduce the effect therebetween. An interval between the information storage layers 12a and 12b may be from several nanometers to hundreds of nanometers, but is not limited thereto.

FIG. 2 is a diagram of a memory device according to another example embodiment.

Referring to FIG. 2, the memory device includes a lower electrode 21 formed on a substrate 20, and an information storage unit 22 formed on the lower electrode 21. Like the information storage unit 12 of FIG. 1, the information storage unit 22 includes a plurality of information storage layers that are spaced apart from one another. The information storage unit 22 is not formed on a front surface of the lower electrode 21, and thus, a partial surface of the lower electrode 21 is exposed.

In FIG. 2, the memory device further includes an insulating layer 23 formed on the lower electrode 21 and the information storage unit 22. The insulating layer 23 may operate as a passivation layer. According to at least this example embodiment, the insulating layer 23 may be formed of a low-k dielectric material having a dielectric constant lower than that of silicon oxide (SiO₂), and may be formed of any one of an organic material such as polymer and an inorganic insulating material.

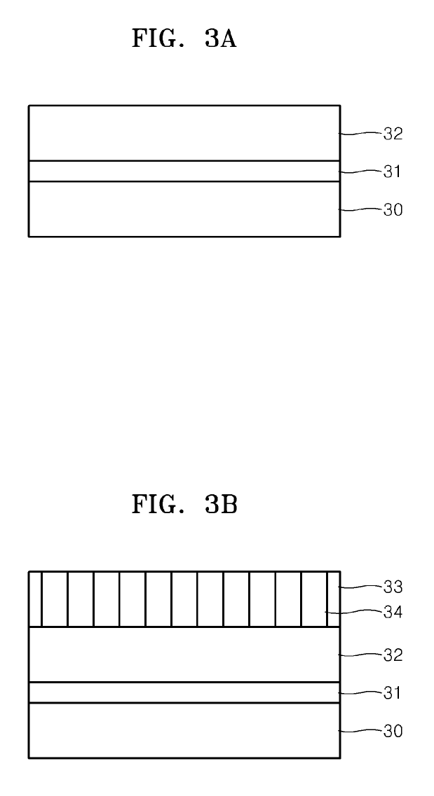

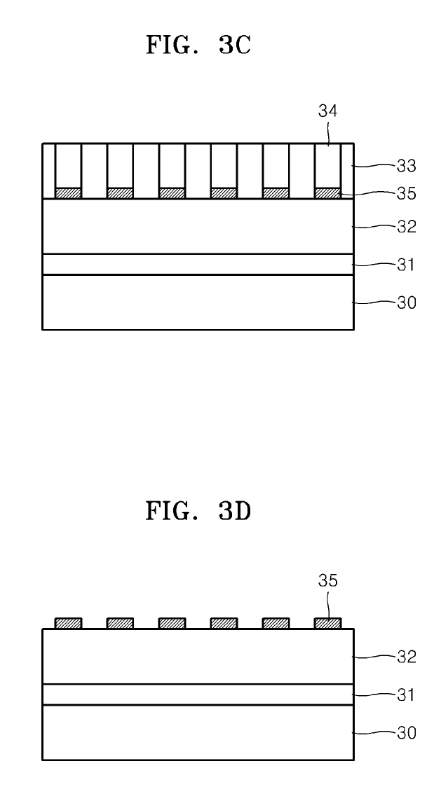

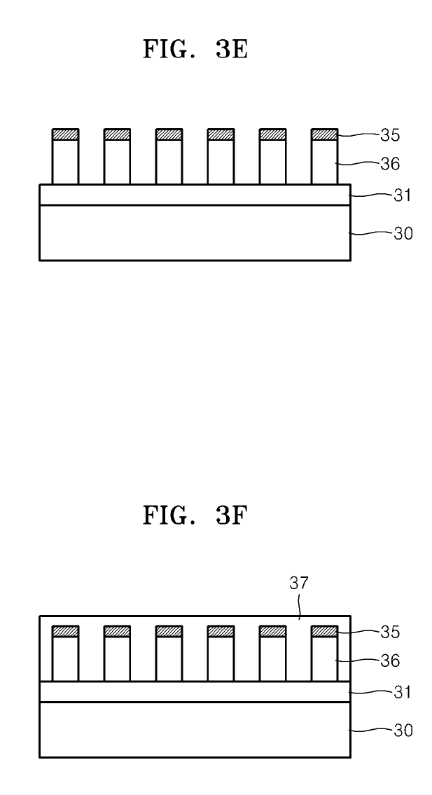

A method of manufacturing a memory device according to an example embodiment will now be described with reference to FIGS. 3A through 3F, which are diagrams for describing the method.

Referring to FIG. 3A, a lower electrode 31 and a material layer 32 for forming an information storage unit are sequentially formed on a substrate 30. In this example, a material of the substrate 30 is not limited as long as it is used for a semiconductor device. In one example, the substrate 30 may be formed of a semiconductor material, such as Si or SiC, glass, etc.

The lower electrode 31 may be formed of a conductive material used for a general electrode material. For example, the lower electrode 31 may be formed of a metal or conductive metal oxide. The material layer 32 may be formed of a ferroelectric material, a ferromagnetic material, or an antiferromagnetic material.

Referring to FIG. 3B, a porous film 33 for patterning the material layer 32 is formed on the material layer 32. The porous film 33 includes a plurality of holes 34 for exposing portions of the material layer 32. The porous film 33 may be a block copolymer or an anodized layer. The block copolymer may include at least two types of polymers connected to each other via a chemical bond, and may have a self-assembly characteristic from several to hundreds of nanometer sizes. Examples of a block copolymer include poly(styrene-b-methyl methacrylate) (PS-b-PMMA), poly(styrene-block-isoprene) (PS-b-PI), poly(styrene-block-ethylene) (PS-b-PE), poly(styrene-block-ethylene propylene) (PS-b-PEP), polystyrene-block-poly(2-vinylpyridine) (PS-b-P2VP), polystyrene-block-poly(4-vinylpyridine) (PS-b-P4VP), polystyrene-block-polybutadiene (PS-b-PB), polyisoprene-block-polyferrocenylsilane (Pl-b-PFS), polystyrene-block-poly(ethylene oxide) (PS-b-PEO), and the like. In methods according to at least this example embodiment, the porous film 33 may be a block copolymer having a porous structure, wherein diameters of pores are from several to dozens of nanometers. In an alternative example embodiment, the porous film 33 may be an alumina anodized layer including a plurality of relatively small or relatively minute holes having nanometer sizes according to anodization.

Referring to FIG. 3C, a mask layer 35 is formed on the material layer 32 through the holes 34 of the porous film 33. In this example, the mask layer 35 may be formed of a material having a different etch characteristic from the material layer

Referring to FIG. 3D, the porous film 33 is removed.

Referring to FIG. 3E, an information storage unit 36 is formed by etching the material layer 32 using the mask layer 35 as an etch mask via a dry etching process. The information storage unit 36 is configured to include a plurality of information storage layers separated from one another. In this example embodiment, each information storage layer may have a width corresponding to a diameter of the mask layer 35 (e.g., from several to hundreds of nanometers). In this example, the mask layer 35 formed on the information storage unit 36 may be selectively removed or may remain.

Referring to FIG. 3F, an insulating layer 37 is formed by coating an insulating material on the lower electrode 31 and the information storage unit 36. The forming of the insulating layer 37 is a selective process and may be omitted. The insulating layer 37 may be formed of a low-k dielectric material, and may be formed of any one of an organic material such as polymer, and an inorganic insulating material.

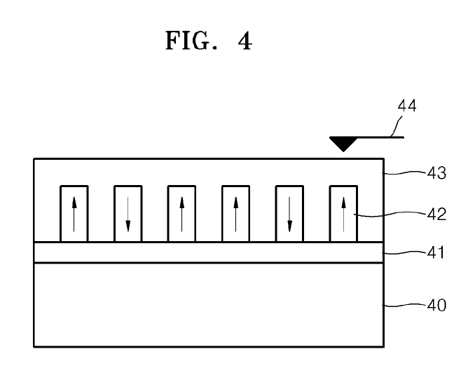

FIG. 4 is a diagram of a memory apparatus including a memory device according to an example embodiment.

Referring to FIG. 4, a lower electrode 41 is formed on a substrate 40, and an information storage unit 42 including a plurality of information storage layers is formed on the lower electrode 41. An insulating layer 43 is formed on the lower electrode 41 and the information storage unit 42. Although shown in this example embodiment, the insulating layer 43 may be omitted. Each information storage layer of the information storage unit 42 may constitute an information unit, and may store data/information of “1” or “0” according to a polarization direction of a dipole. Information may be read from or written to the information storage unit 42 using a probe 44.

As described above, according to one or more example embodiments, an information maintaining characteristic (e.g., a retention characteristic) of a memory device may be improved by forming a plurality of recording layers having a nanometer size of the memory device such that the recording layers are not affected by each other.

It should be understood that example embodiments described therein should be considered in a descriptive sense only and not for purposes of limitation. Descriptions of features or aspects within each example embodiment should typically be considered as available for other similar features or aspects in other example embodiments.

What is claimed is:

1. A memory device comprising:
a lower electrode formed on a substrate; and
an information storage unit formed on the lower electrode, the information storage unit including a plurality of information storage layers spaced apart from one another, each of the plurality of information storage layers being an information unit.

2. The memory device of claim 1, wherein the information storage unit is formed of a ferroelectric material, a ferromagnetic material, or an antiferromagnetic material.

3. The memory device of claim 1, further comprising:
an insulating layer formed on the lower electrode and the information storage unit.

4. The memory device of claim 3, wherein the insulating layer is formed of a low-k dielectric material having a dielectric constant lower than silicon oxide (SiO₂).

5. The memory device of claim 1, wherein an interval between the plurality of information storage layers is between several nanometers and hundreds of nanometers.

6. A method of manufacturing a memory device, the method comprising:
forming a lower electrode on a substrate;
forming a material layer on the lower electrode;
forming a porous film on the material layer;
forming a mask layer on the material layer through the porous film; and
forming an information storage unit by etching the material layer using the mask layer as an etch mask.

7. The method of claim 6, wherein the material layer is formed of a ferroelectric material, a ferromagnetic material, or an antiferromagneic material.

8. The method of claim 6, wherein the porous film includes a plurality of holes exposing the lower electrode.

9. The method of claim 6, wherein the porous film is a block copolymer or an anodized layer.

10. The method of claim 9, wherein the block copolymer is poly(styrene-b-methyl methacrylate) (PS-b-PMMA), poly(styrene-block-isoprene) (PS-b-PI), poly(styrene-block-ethylene) (PS-b-PE), poly(styrene-block-ethylene propylene) (PS-b-PEP), polystyrene-block-poly(2-vinylpyridine) (PS-b-P2VP), polystyrene-block-poly(4-vinylpyridine) (PS-b-P4VP), polystyrene-block-polybutadiene (PS-b-PB), polyisoprene-block-polyferrocenylsilane (PI-b-P FS), or polystyrene-block-poly(ethylene oxide) (PS-b-PEO).

11. The method of claim 6, further comprising:
removing the mask layer after forming the information storage unit.

12. The method of claim 6, further comprising:
forming an insulating layer on the information storage unit.
